(19) United States
(12) Patent Application Publication
(10) Pub. No.: US 2012/0318852 A1
(43) Pub. Date: Dec. 20, 2012

(54) METHOD OF PREVENTING EMI FOR A FASTENING HOLE IN A CIRCUIT BOARD AND A FIXTURE THEREFOR

(76) Inventors: Wen-Bing ZHOU, New Taipei City (TW); Youg-Jun LIAO, New Taipei City (TW); Qiang WANG, New Taipei City (TW); Hung-Che CHEN, New Taipei City (TW)

(21) Appl. No.: 13/524,245

(22) Filed: Jun. 15, 2012

(30) Foreign Application Priority Data
Jun. 17, 2011 (CN) 201110163353.X

(51) Int. Cl. B23K 31/02; H05K 9/00

(52) U.S. Cl. 228/180.21; 174/350

(57) ABSTRACT

A method of preventing EMI for a fastening hole in a circuit board includes the steps of providing a circuit board which includes a plurality of fastening holes extending through opposite first and second surfaces thereof and a plurality of solder pads disposed on the second surface, each fastening hole being surrounded by the solder pads; disposing an electronic component on the first surface; positioning the circuit board on a fixture such that the solder pads are not covered by the fixture; and wave soldering the circuit board so that the electronic component is fixed to the circuit board and the solder pads are attached with solder materials.

### CROSS REFERENCE TO RELATED APPLICATION

This application claims priority of Chinese Patent Application no. 201110163353.X, filed on Jun. 17, 2011, the disclosure of which is incorporated herein by reference.

### BACKGROUND OF THE INVENTION

1. Field of the Invention

The invention relates to a circuit board, more particularly to a method of preventing EMI for a fastening hole in a circuit board and a fixture therefor.

2. Description of the Related Art

A conventional circuit board, for example a motherboard of a computer, is formed with fastening holes for fastening the same to a computer housing. To prevent EMI (Electromagnetic Interference), conventionally, solder pads are provided on a bottom surface of the circuit board and surround the fastening holes, and by using a tin printing process, the solder pads are attached with solder materials. However, under a situation where only a top surface of the circuit board is mounted with the electronic component, if the bottom surface of the circuit board has to undergo tin printing again just to prevent EMI, the cost for making the conventional circuit board is increased.

### SUMMARY OF THE INVENTION

Therefore, an object of the present invention is to provide a method of preventing EMI for a fastening hole in a circuit board and that can resolve the aforementioned drawback of the prior art.

According to one aspect of this invention, a method of preventing electromagnetic interference (EMI) for a fastening hole in a circuit board comprises the steps of:
providing a circuit board, the circuit board including a board body and a plurality of solder pads, the board body having opposite first and second surfaces, and a plurality of fastening holes extending through the first and second surfaces, the solder pads being disposed on the second surface, each of the fastening holes being surrounded by the solder pads;
disposing an electronic component on the first surface of the board body;
positioning the circuit board on a fixture such that the solder pads that surround the fastening holes are not covered by the fixture; and
wave soldering the circuit board by passing the circuit board through a tin oven so that the electronic component is fixed to the board body and the solder pads are attached with solder materials.

Because the solder pads of the present invention are not covered by the fixture, when the circuit board passes through the tin oven for wave soldering, apart from fixing the electronic component to the first surface, the solder pads on the second surface are simultaneously attached with the solder materials, so that the fastening holes in the second surface are prevented from EMI. In comparison with the conventional tin printing method, the method of the present invention can save manufacturing cost and simply manufacturing process.

Further, the board body further includes a plurality of orifices surrounding each of the fastening holes and corresponding in position to the solder pads.

Further, each of the fastening holes is surrounded by more than four said solder pads.

Further, each of the fastening holes is surrounded by eight said solder pads that are equally angularly spaced apart from each other.

Another advantage of this invention resides in that by providing more solder pads around the fastening holes so as to decrease the area of each solder pad, the amount of solder materials attached to each solder pad may be reduced, thereby resolving the problem of surface unevenness caused by excessive amount of solder materials attached to the solder pads.

According to another aspect of this invention, a fixture used in the aforesaid method has a frame shape defining an open area for registering with the second surface of the board body and for exposing the fastening holes when the circuit board is positioned on the fixture.

By providing the fixture with a frame shape, when the fixture carries the circuit board to pass through the tin oven, the influence of the high-temperature tin oven on the fixture can be reduced, so that the service life of the fixture can be prolonged.

### BRIEF DESCRIPTION OF THE DRAWINGS

Other features and advantages of the present invention will become apparent in the following detailed description of the embodiment with reference to the accompanying drawings, of which:

FIG. 1 is a flow chart, illustrating the steps involved in a method of preventing EMI for a fastening hole in a circuit board according to an embodiment of the present invention;

FIG. 2 is a schematic view of the circuit board of the embodiment;

FIG. 3 is a schematic view of the embodiment, illustrating the circuit board being positioned on a fixture; and

FIG. 4 is a fragmentary enlarged schematic view of the circuit board of the embodiment.

### DETAILED DESCRIPTION OF THE PREFERRED EMBODIMENT

The above-mentioned and other technical contents, features, and effects of this invention will be clearly presented from the following detailed description of one embodiment in coordination with the reference drawings.

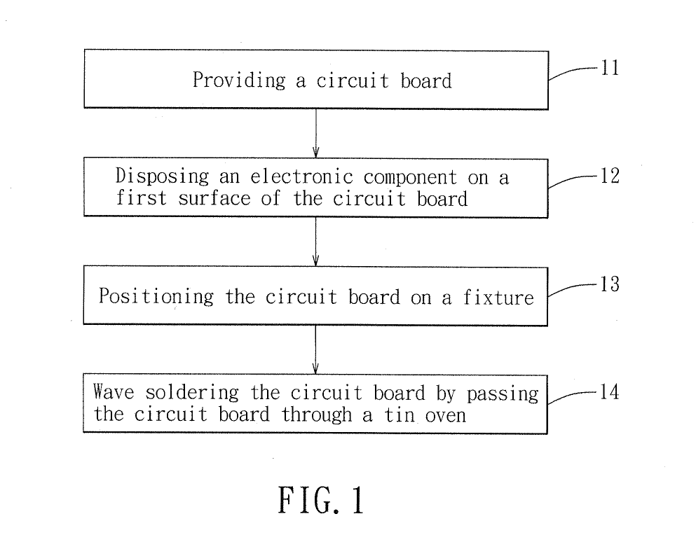

Referring to FIG. 1, a method of preventing EMI for a fastening hole in a circuit board according to an embodiment of the present invention comprises steps 11-14. In this embodiment, the circuit board is exemplified as a motherboard of a computer.

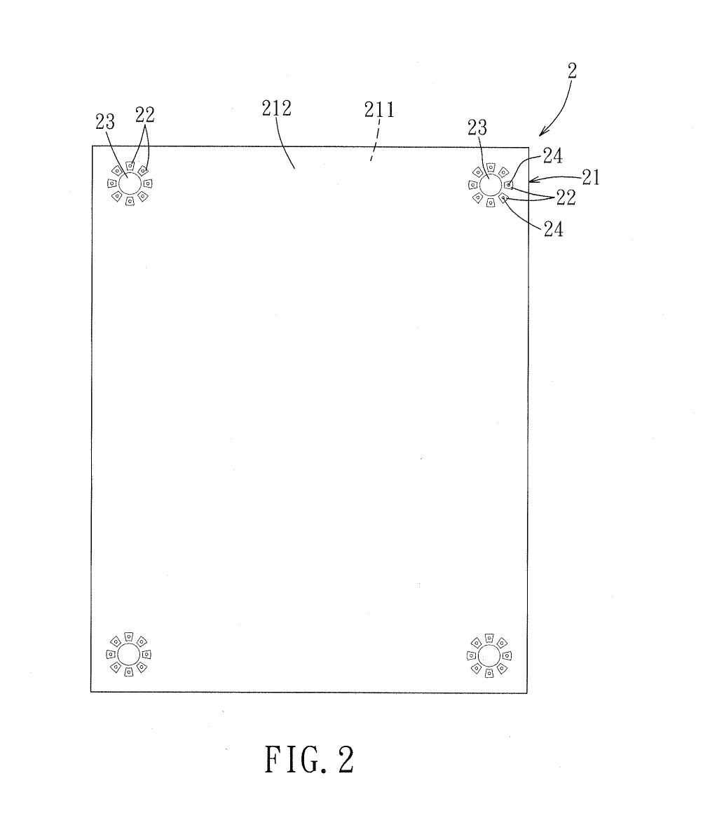

In step 11, a circuit board 2 is provided. Referring to FIG. 2, the circuit board 2 includes a board body 21 and a plurality of solder pads 22. The board body 21 has a first surface 211 for mounting thereon an electronic component (not shown), a second surface 212 opposite to the first surface 211, and a plurality of spaced-apart fastening holes 23 which are configured as through holes that extend through the first and second surfaces 211, 212 of the board body 21. The solder pads 22 are disposed on the second surface 212, and surround each of the fastening holes 23.

In this embodiment, the circuit board 2 has only one surface mounted with the electronic component. That is, the circuit board 2 has only the first surface 211 mounted with the electronic component. The board body 21 further includes eight orifices 24 surrounding each of the fastening holes 23. The second surface 212 has eight solder pads 22 surrounding each of the fastening holes 23 and equally angularly spaced apart from each other. Each two adjacent ones of the solder pads 22 define therebetween an included angle of 45°. Each of the orifices 24 is located at a position corresponding to a respective one of the solder pads 22 and for grounding. However, each of the orifices 24 may not necessarily be disposed thereat.

In step 12, the electronic component is disposed on the first surface 211 of the board body 21. In this step, the electronic component that is to be soldered fixedly on the first surface 211 is placed on the circuit board 2. For example, the terminals of the electronic component are inserted on the first surface 211 (i.e., DIP insert component).

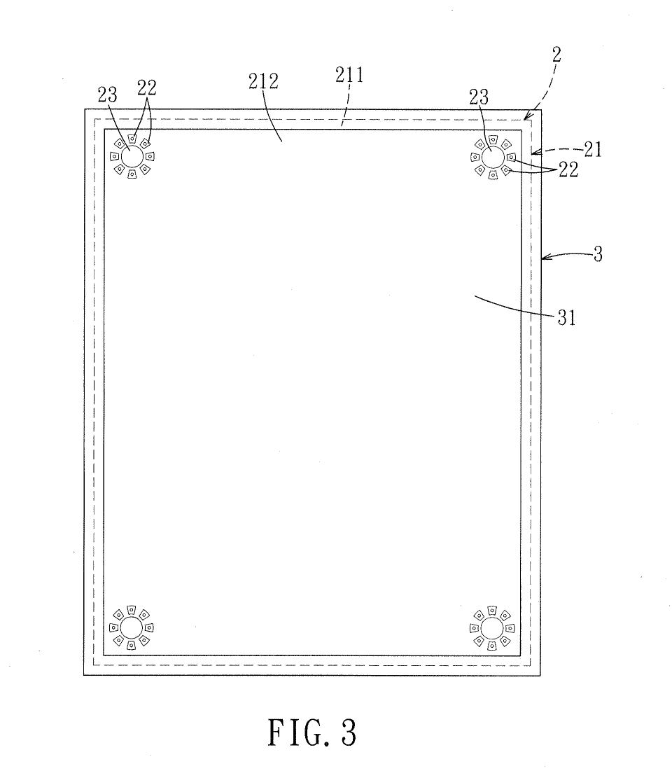

In step 13, the circuit board 2 is positioned on a fixture 3. Referring to FIG. 3, the fixture 3 of this embodiment has a frame shape defining an open area 31. When the circuit board 2 is placed on the fixture 3 (for example, through an interlocking or fastening means), the second surface 212 of the board body 21 faces the open area 31, and the solder pads 22 are exposed from the open area 31 and are not covered by the fixture 3.

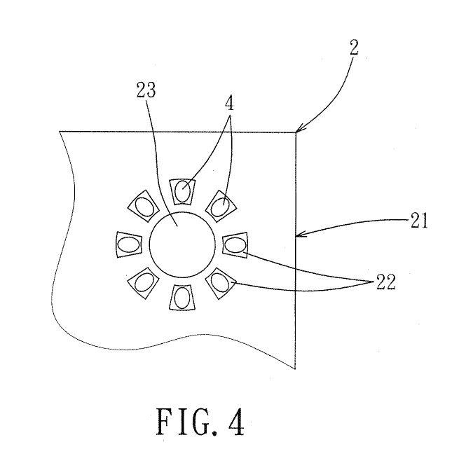

In step 14, the circuit board 2 is wave soldered in a tin oven. Referring to FIG. 4, in combination with FIG. 3, the circuit board 2 which is positioned on the fixture 3 is passed through a tin oven (not shown) to process wave soldering. Apart from soldering the electronic component fixedly to the first surface 211 of the board body 21, solder materials 4 are attached to the solder pads 22 and covered the holes, simultaneously. In other words, the attachment of the solder materials to the solder pads 22 4 and the fixing of the electronic component to the board body 21 are accomplished simultaneously when the circuit board 2 passes through the tin oven.

It is worth mentioning that, when the number of the solder pads 22 that surround each fastening hole 23 increases (for example, eight in this embodiment), the area occupied by each of the solder pads 22 decreases. When the circuit board 2 passes through the tin oven to process wave soldering, each solder pad 22 is attached with less amount of solder material 4. As such, when the solder materials are solidified, the second surface 212 of the board body 21 is substantially flat. This resolves the problem of having an uneven or bumpy surface caused by excessive amount of solder materials 4 attached to the solder pads 22.

Additionally, when a portion of the electronic component requires to be soldered to the first surface 211 of the board body 21 using a surface mount technology (SMT), prior to step 12, surface mount and reflow operations of the electronic component may be performed first on the first surface 211 of the board body 21.

In summary, by positioning the circuit board 2 on the fixture 2 such that the solder pads 22 are not covered by the fixture 3 but are instead exposed, when the circuit board 2 passes through the tin oven to process wave soldering, apart from soldering fixedly the electronic component on the first surface 211 of the board body 21, the solder pads 22 on the second surface 212 of the board body 21 are also attached with solder materials. Thus, the fastening holes 23 in the second surface 212 of the board body 21 have an EMI shielding effect. In comparison with the conventional tin printing method, the method of the present invention can save manufacturing cost and simplify manufacturing process.

Furthermore, by distributing more solder pads 22 around each of the fastening holes 23 so as to decrease the area of each solder pad 22, the amount of solder materials 4 attached to each solder pad 22 is reduced, so that the second surface 212 has a flat surface, thereby resolving the problem of having an uneven or bumpy surface caused by excessive amount of solder materials 4 attached to the solder pads 22.

Moreover, by providing the fixture 3 with a frame shape, when the fixture 3 carries the circuit board 2 to pass through the tin oven, the influence of the high-temperature tin oven on the fixture 3 is reduced, so that the service life of the fixture 3 can be prolonged. Hence, the object of this invention can be realized.

While the present invention has been described in connection with what is considered the most practical embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A method of preventing EMI for a fastening hole in a circuit board, comprising:
providing a circuit board, the circuit board including a board body and a plurality of solder pads, the board body having opposite first and second surfaces, and a plurality of fastening holes extending through the first and second surfaces, the solder pads being disposed on the second surface, each of the fastening holes being surrounded by the solder pads;
disposing an electronic component on the first surface of the board body;
positioning the circuit board on a fixture such that the solder pads that surround the fastening holes are not covered by the fixture; and
wave soldering the circuit board by passing the circuit board through a tin oven so that the electronic component is fixed to the board body and the solder pads are attached with solder materials.

2. The method as claimed in claim 1, wherein the board body further includes a plurality of orifices surrounding each of the fastening holes and corresponding in position to the solder pads.

3. The method as claimed in claim 1, wherein each of the fastening holes is surrounded by more than four said solder pads.

4. The method as claimed in claim 3, wherein each of the fastening holes is surrounded by eight said solder pads which are equally angularly spaced apart from each other.

5. A fixture for a method of preventing EMI for a fastening hole in a circuit board, the circuit board having opposite first and second surfaces and a plurality of fastening holes extending through the first and second surfaces, said fixture having a frame shape that defines an open area for registering with the second surface of the circuit board and for exposing the fastening holes when the circuit board is positioned on the fixture.
